(19) United States
(12) Patent Application Publication
(10) Pub. No.: US 2006/0097744 A1
(43) Pub. Date: May 11, 2006

(54) Apparatus and method for inspecting thin film transistor active matrix substrate

(76) Inventors: Go Tejima, Toyoda-shi, Aichi (JP); Toshiaki Ueno, Kanagawa (JP)

Correspondence Address: OHLANDT, GREELEY, RUGGIERO & PERLE, LLP, ONE LANDMARK SQUARE, 10TH FLOOR, STAMFORD, CT, 06901, US

(21) Appl. No.: 10/541,279

(22) PCT Filed: Jan. 28, 2004
(86) PCT No.: PCT/JP04/00788

§ 371 Date: Jul. 1, 2005

(30) Foreign Application Priority Data
Feb. 7, 2003 (JP) 2003-030511

(51) Int. Cl. G01R 31/00

(52) U.S. Cl. 324/770

(57) ABSTRACT

A method for inspecting a thin film transistor active matrix substrate comprises a step for opposing a probe to the substrate, a step for supplying a dielectric fluid between the substrate and the probe, a step for supplying power to a closed circuit containing the substrate and the probe, and a step for sensing a signal passed through the closed circuit by the power supply. Using this method, a non-contact TFT array substrate inspection apparatus with high throughput, which is also suitable for organic EL substrates, can be realized.

### FIELD OF THE INVENTION

The present invention relates to an apparatus and a method for inspecting a thin-film transistor active matrix substrate.

### DISCUSSION OF THE BACKGROUND ART

Active matrix systems that use thin-film transistors (TFTs) in order to realize high image quality have recently become very commonly employed for flat panel displays, typically liquid crystal displays and organic EL displays. TFT array testing wherein the operation of a completed TFT array is electronically tested before the step for forming the TFT array on a glass substrate, that is, the step for injecting liquid crystals or applying an organic EL material, is very important for preventing waste of expensive liquid crystals and organic EL materials in the production of TFT-type liquid crystal and organic EL panels. That is, electrical defects in a TFT circuit that drives specific pixels can be discovered by TFT array testing prior to the step for injecting liquid crystals or organic EL application, and the yield of subsequent steps that add to cost can be improved by implementing measures for correcting defective pixels or removing substrates with defective pixels from these production steps.

FIG. 2 shows an example of a typical single pixel TFT drive circuit of a liquid crystal panel. Reference 50 in the figure is a data line, 51 is a gate line, 52 is a common line, 53 is a liquid crystal, and 54 is a transparent electrode that uses ITO (indium tin oxide). When several pixels are formed in a matrix on a glass substrate, several drive circuits as shown in FIG. 2 are employed, and this arrangement is called a TFT array. The above-mentioned TFT array test is conducted before the liquid crystal 53 is injected; therefore, the test is performed with several ITO electrodes 54 of pixels in an exposed state. The method whereby the TFT is electrically switched and checked to see if a normal potential is being generated at the surface of ITO electrode 54 is generally used to test this type of drive circuit. The selected TFT transistor can be turned ON by applying voltage to gate line 51 of the drive circuit under test with voltage having been applied to data line 50. The TFT transistor can be judged normal as long as the same voltage as the applied voltage of the data line is generated at ITO electrode 54.

FIG. 3 shows an example of a typical TFT drive circuit of one pixel of an organic EL panel. Reference 42 in FIG. 3 is a drive transistor, 50 is a data line, 51 is a gate line, 52 is a common line, 54 is an ITO electrode, 55 is an organic EL, and 56 is a drive line. An organic EL panel differs from a liquid crystal panel in that a drive current of 10 μA is needed for auto-emission by the organic EL itself. Therefore, it differs from a TFT array for liquid crystals in that drive transistor 42 and drive line 56 for feeding drive current are added. As with liquid crystal panels, it is preferred that TFT array testing of organic EL panels be performed before the costly step of applying an organic EL 55, that is, with the ITO electrode 54 is an exposed state.

Contact-free inspection of pixels is necessary because TFT array tests are conducted with ITO electrode 54 on the substrate in an exposed state. Moreover, high throughput is necessary from an economic standpoint because there are many pixels on a thin-film transistor active matrix substrate. Contact-free inspecting apparatuses such as shown in JP Kokai Unexamined Patent Publication 6[1994]-27494 and JP Kokai Unexamined Patent Publication 2002-22789 have been proposed as this type of inspecting apparatus. The apparatus cited in JP Kokai Unexamined Patent Publication 6[1994]-27494 is a device for checking for the presence of pixel defects by bringing a probe close to a substrate to which alternating current has been applied and measuring the voltage generated in the probe. Moreover, the apparatus cited in JP Kokai Unexamined Patent Publication 2002-22789 is an apparatus for checking for the presence of defects by bringing a probe that is larger than the pixels close to a drive circuit on a pixel to which pulse current has been applied and measuring the voltage generated in the probe.

However, sufficient measurement sensitivity cannot be realized by means of the apparatuses cited in JP Kokai Unexamined Patent Publication 6[1994]-7494 and JP Kokai Unexamined Patent Publication 2002-22789 unless the probe is brought very close to the substrate because the dielectric constant of air is small, and a probe having a wide detection surface area cannot be used to inspect substrates for panels with a low degree of flatness and a wide surface area. Therefore, there are problems in that, in addition to means for precisely controlling the space between the probe and the pixel, inspection throughput is slow because the probe must move many times.

Furthermore, in the case of substrates for organic EL panels, the load applied to the terminals of drive transistor 42 connected to ITO electrode 54 is in a disconnected state and current does not flow to transistor 42 before the organic EL has been applied. There are methods whereby a pre-inspection load Ct is applied parallel to ITO electrode 54 as shown by the broken line in FIG. 3, but there are problems in that extra space on the substrate is necessary and the number of steps involved in making the substrate is increased. Moreover, it is preferred that organic EL panels that are current-driven be inspected by allowing the same current as actually used to flow through the panel, but when this current flows through the panel using the apparatuses cited in JP Kokai Unexamined Patent Publication 6[1994]-7494 and JP Kokai Unexamined Patent Publication 2002-22789, which are apparatuses for inspecting voltage-driven liquid crystal panels, a large applied voltage becomes necessary and, as a result, dielectric breakdown occurs between the substrate and the probe.

The present invention solves the above-mentioned problems, the object thereof being to provide a contact-free apparatus and method for inspecting thin-film transistor active matrix substrates that can also be used to test organic EL substrates at a high throughput.

### SUMMARY OF THE INVENTION

The present invention provides an inspecting apparatus comprising a signal supply means for supplying signals to a thin-film transistor active matrix substrate; a probe positioned opposite the substrate; and a detection means for detecting signals flowing to the probe, this inspecting apparatus being characterized in further comprising a fluid supply means for supplying a dielectric fluid between the substrate and the probe.

By means of this apparatus, a high capacitance is obtained; high-sensitivity inspection is possible, even if the space between the substrate and the probe is wide; and control of the space is simplified because a dielectric fluid is filled between the substrate and the probe at the time of the inspection. Moreover, a probe with a wide surface area can be used, even if the substrate has a small degree of flatness, and inspection throughput can be dramatically improved because the space can be enlarged. Furthermore, an ITO electrode in an exposed state and a probe can be joined under high capacitance and a closed circuit of low impedance can be formed between the substrate and the probe by filling a dielectric fluid between the substrate and probe; therefore, inspections can also be performed on substrates for organic EL panels without applying a measurement load.

The signal supply means preferably comprises a signal supply means for supplying non-standing wave signals.

The dielectric fluid preferably comprises a liquid of polar molecules.

The dielectric fluid preferably comprises water.

The probe is preferably such that it has multiple electrodes for inspection.

The detection means preferably comprises a detection means for detecting the current flowing to the probe.

Moreover, the present invention provides a method for inspecting a thin-film transistor active matrix substrate characterized in that it comprises a step for bringing the probe opposite the thin-film transistor active matrix substrate; a step for supplying a dielectric fluid between the substrate and the probe; a step for supplying signals to a closed circuit comprising the substrate, the dielectric fluid, and the probe; and a step for detecting signals flowing to the closed circuit.

The substrate preferably comprises a substrate for liquid-crystal panels.

The substrate preferably comprises a substrate for organic EL panels.

The detection surface area of the probe is preferably wider than the surface area of the pixels on the substrate.

The inspection method preferably further comprises a step for discharging the dielectric fluid from between the substrate and the probe.

The distance between the substrate and the probe is preferably controlled by the amount of dielectric fluid that is supplied.

### BRIEF DESCRIPTION OF THE DRAWINGS

FIG. 1 is a general drawing of an inspecting apparatus showing a preferred embodiment of the present invention.

FIG. 2 is a drawing showing a typical single-pixel TFT drive circuit of a liquid-crystal panel.

FIG. 3 is a drawing showing a typical single-pixel TFT drive circuit of an organic EL panel.

FIG. 4 is a close-up view of the substrate and probe of another embodiment of the present invention

FIG. 5 is an enlargement of one pixel of a TFT array and the drive circuit thereof of a preferred embodiment of the present invention.

FIG. 6 is a descriptive drawing of the inspection signals of the present invention. (a) represents the inspection signal of the embodiment, (b) is the current waveform when there are no pixel defects in the array. Moreover, (c) shows an example of another inspection signal and (d) shows the inspection waveform when there are no pixel defects.

FIG. 7 is a drawing showing the movement of the probe for a preferred embodiment of the present invention.

FIG. 8 is a close-up view of the substrate and probe of a preferred embodiment of the present invention.

FIG. 9 is a drawing showing changes in the dielectric constant of water with temperature.

FIG. 10 is a drawing showing the probe end face of a preferred embodiment of the present invention.

FIG. 11 is a close-up view of the substrate and the probe for another preferred embodiment of the present invention.

### DETAILED DESCRIPTION OF THE PREFERRED EMBODIMENT

Preferred embodiment of the inspecting apparatus and method of the present invention will now be described in detail while referring to the attached drawings. The inspection of a substrate for an organic EL panel is described in detail with the present embodiment, but it is clear that the inspection of a substrate for a liquid-crystal panel can be performed according to the same theory and with the same apparatus.

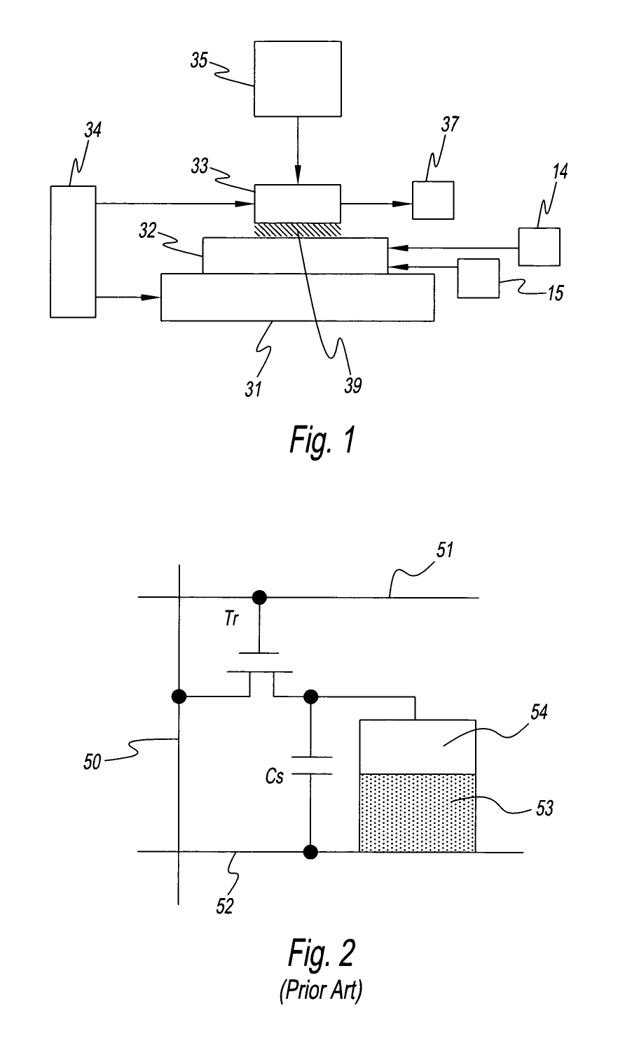

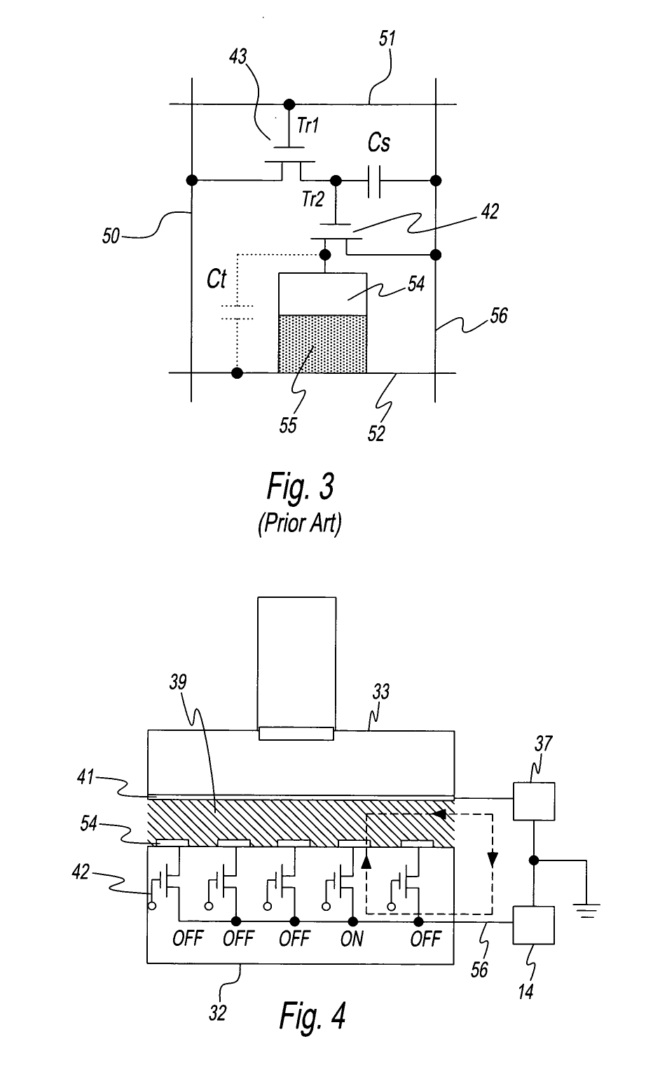

FIG. 1 shows the general structure of a preferred embodiment of the inspecting apparatus of the present invention.

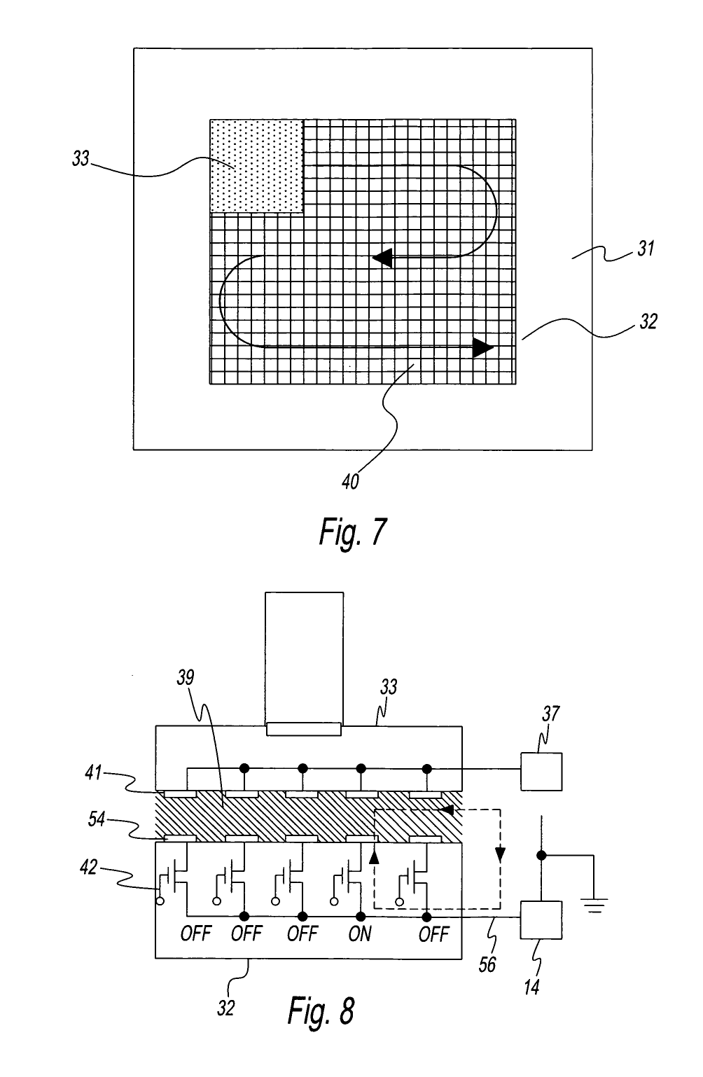

Reference 14 in FIG. 1 is a signal supply device, 15 is a pixel selector, 31 is an X-Y stage, 32 is a thin-film transistor active matrix substrate for an organic EL panel, 33 is a probe, 34 is a device for controlling the position of the X-Y stage and the probe, 35 is a water supply device, 37 is a signal detector, and 39 is water. As shown in FIG. 7, pixels 40 that are 100 μm×100 μm in size are arranged in matrix form on substrate 32 disposed on X-Y stage 31. Device 34 for controlling position is connected between stage 31 and probe 33, and moves stage 31 in the X-Y direction to align substrate 32 and moves probe 33 in the X, Y, Z directions for alignment at the inspection position. The space between substrate 32 and probe 33 is controlled by measuring the distance between the substrate and the probe by optical means using a laser, and by mechanical position control with a piezo element. Water supply device 35 is connected to probe 33 and supplies water 39 as a dielectric fluid to probe 33. The dielectric fluid here is a fluid with a large dielectric constant and corresponds to methyl alcohol, ethyl alcohol, water, or another fluid of polar molecules. However, pure water was used in the present embodiment because it will not corrode substrate 32 and can easily be used in combination with the equipment that is used in the production process. The conductivity of the pure water that was used was 0.06 μS/cm or less. Water supply device 35 can be part of a special inspection device as in the present embodiment or it can be the standard substrate washing device such as devices that are used in to produce substrate 32. Water tubes 20 for introducing and discharging water 39 are made in each of the four end faces of probe 33, as shown in FIG. 10, and a nitrogen gas flow path 21 is formed around the outside so that water 39 will not leak outside the probe. Water 39 that has been supplied from water supply device 35 is supplied from water tube 20 at any end face of probe 33 to between substrate 32 and probe 33 and is discharged from water tube 20 on the opposite side. Moreover, pixel selector 15 is connected to substrate 32 and supplies signals that select the pixel under test. Signal supply device 14, which is a signal supply means, supplies the same inspection signals as actually used during operation to substrate 32. Current detector 37, which is a detection means, is connected to probe 33 and checks for defects and the state of defects by detecting the current flowing to the substrate and evaluating the status of the circuit of each pixel.

FIG. 8 is a close-up view of substrate 32 and probe 33. ITO electrodes 54 connected to drive transistors 42 are disposed on substrate 32 as previously described. Each ITO electrode 54 corresponds to the respective pixel on the panel in FIG. 8. A plurality of electrodes 41 that are 100 μm×100 μm in size are arranged on the side of probe 33 opposite substrate 32 in the same array form as for the pixels on substrate 32. When electrodes 41 in array form are used, it is possible to reduce the effect of capacitance induced between wiring other than ITO electrodes 54, such as drive line 56, and probe 33 and to realize high-sensitivity inspection. Moreover, inspections signals that have been supplied to drive line 56 are supplied to pixels corresponding to drive transistor 42 in a conducting state (ON) by pixel selector 15 and the substrate is checked for the presence and status of defective pixels by detecting these signals using current detector 37 connected to electrode 41.

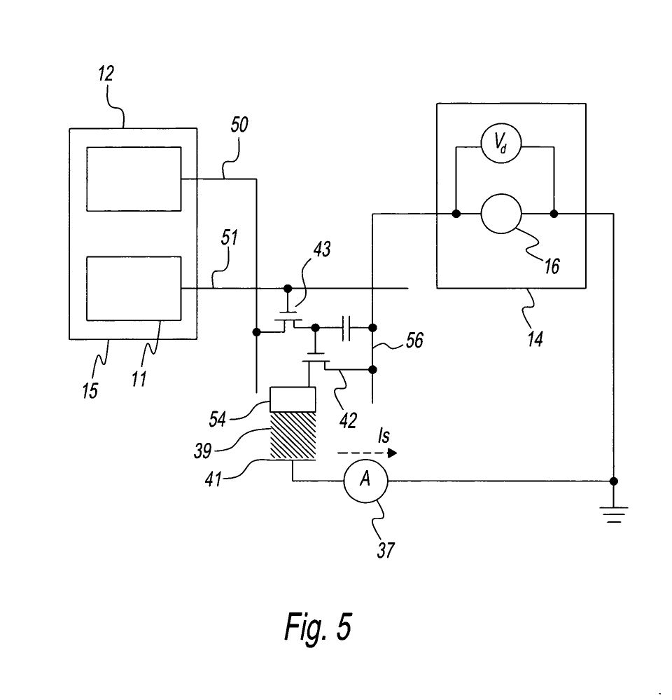

FIG. 5 is an explanatory drawing of one pixel of a TFT array used in an organic EL panel and the drive circuit thereof. Reference 11 in FIG. 5 is a gate line drive circuit, 12 is a data line drive circuit, 16 is an alternating-current power source, and 43 is a transistor for pixel selection. Gate line drive circuit 11, which is part of pixel selector 15, is connected to all or some of a plurality of gate lines 51 and a pre-determined voltage is applied to gate lines 51 that are connected to the pixel under test. Data line drive circuit 12, which is a part of pixel selector 15, is connected to all or some of a plurality of data lines 50 and a pre-determined voltage is applied to data lines 50 that are connected to the pixel under test. Transistor 43 for pixel selection is connected to the gate of drive transistor 42 and controls the operating state of drive transistor 42. When voltage is applied to data line 50 and gate line 51, transistor 15 for pixel selection is turned on and drive transistor 42 is in a conducting state (ON). Alternating-current power source 16, which is part of signal supply device 14, is connected to drive line 56 and supplies pulse wave signals of non-standing wave signals. Non-standing wave signals here mean pulse wave signals, sine-wave signals, and other signals wherein the voltage or current changes over time.

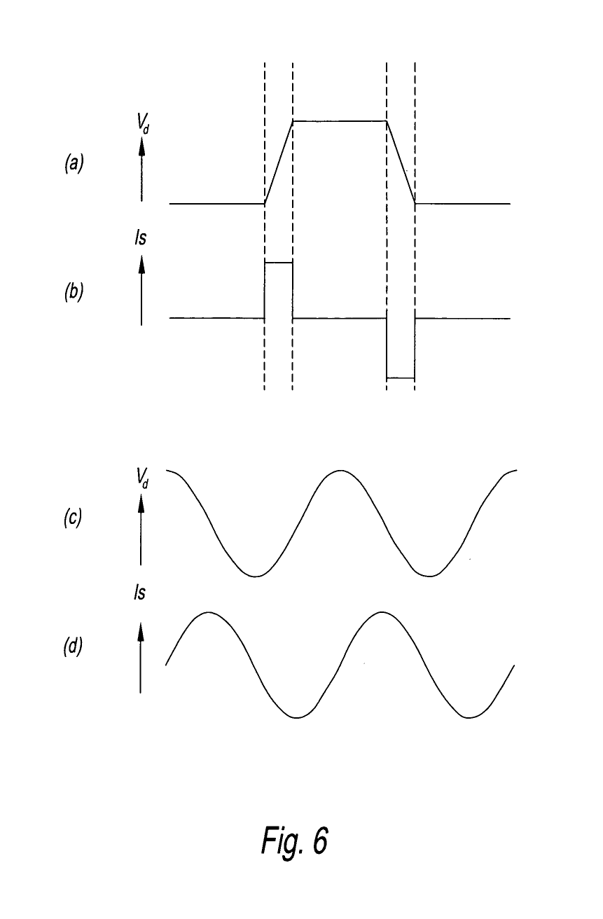

Operation of the inspecting apparatus will now be described. First, substrate 32 under test is set on stage 31 and current detector 37 and pixel selector 15 are connected to substrate 32. Then stage 31 and probe 33 are moved by position control device 34. Probe 33 is moved to above the inspection position on substrate 32 and probe 33 is brought close to substrate 32. The space between substrate 32 and probe 33 in the present embodiment is 10 μm. Moreover, water supply device 35 begins to supply water 39 between substrate 32 and probe 33. Voltage is applied between data line 50 and gate line 51 of the first pixel to be inspected in this state and drive transistor 42 of the pixel to be inspected is brought to a conducting state. Moreover, inspection signals are applied to a closed circuit by applying pulse wave signals as shown in FIG. 6(a) from signal supply device 14. The current of 10 μA necessary for emission by the organic EL is applied in order to perform the inspection in a state similar to the state under which the panel is actually used. Moreover, the determination frequency is 10 MHz. The current flowing to the closed circuit at this time is detected by current detector 37. If there are no defects in the pixel, the differential waveform current Is found from the applied voltage Vd and the capacitance of water 39 (Is=Vd/Z) is detected, as shown in FIG. 6(b). If there is no current and/or the current is extremely small, it is concluded that there is a defect in transistor 43 for pixel selection, drive transistor 42, etc. Moreover, if there is a large current flowing or if signals of a different waveform are detected, it is concluded that there is a leak from drive transistor 42, ITO electrode 54, etc. Defects are thereby detected in the pixel under test.

When the inspection of one pixel is completed in this way, the same inspection is performed by applying voltage to data line 50 and gate line 51 of an adjacent pixel. Inspection of all pixels facing probe 33 is thereby performed in succession. Once all of the pixels have been inspected, probe 33 is moved as shown in FIG. 7 and the same inspection is repeated on all pixels on substrate 32.

It should be noted that fresh water 39 is continuously supplied throughout the inspection in order to facilitate the movement of probe 33 and prevent contamination of the dielectric fluid by impurities. It is possible at this time to continuously supply water 39 in a stable manner to pixels being inspected by supplying water from water tube 20 positioned in the end face of probe 33 that serves as the front of the probe in the direction of movement thereof and to discharge water from water tube 20 on the opposite side.

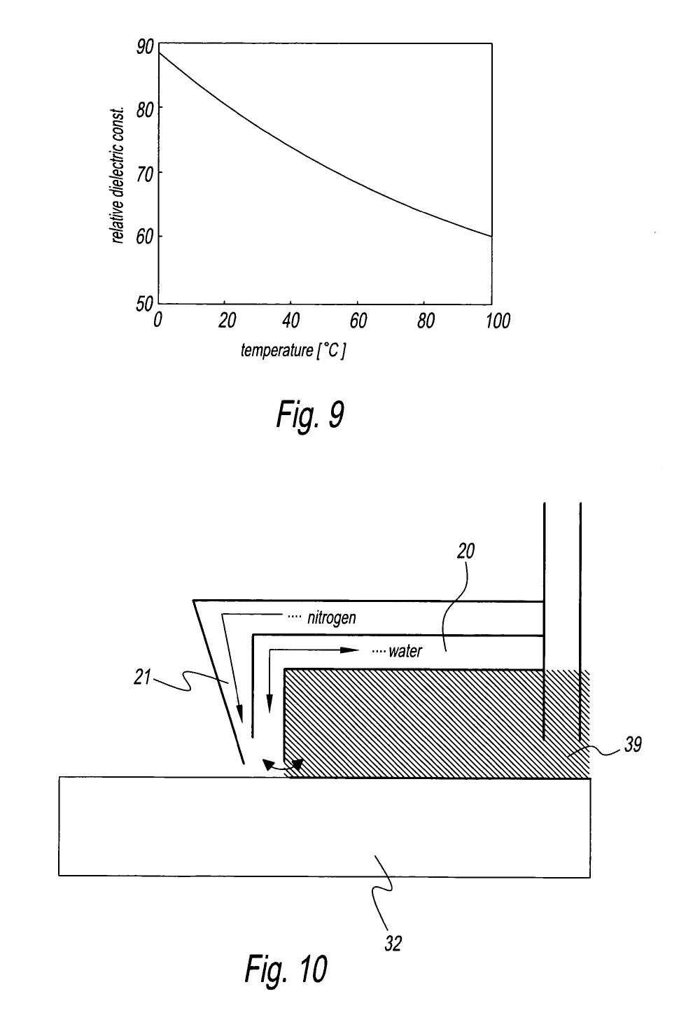

Pulse-shaped signals as in FIG. 6(a) were used as the inspection signals in the present embodiment, but sine-wave signals such as in FIG. 6(c) can also be used. In this case, as long as there are no defects in the pixels, current Is, the phase of which has changed by 90° as shown in FIG. 6(d), will be detected at current detector 37. Moreover, a relative dielectric constant of water 39 changes with temperature as shown in FIG. 9; therefore, when the inspection takes a long time or the inspection is performed in an environment in which temperature changes, and under similar circumstances, a more precise inspection is possible as long as a temperature control device is installed and the temperature of water 39 is held constant.

Furthermore, it is possible to simultaneously select all or any number of pixels before performing the individual inspection of each pixel and to perform a higher throughput inspection by adopting an inspection method whereby, of the selected pixels, those pixels facing probe 33 are checked as a group for defective pixels and individual pixels are inspected only when there are defective pixels [found for the group].

By means of the above-mentioned embodiment, it is possible to inspect pixels even if the space between the probe and the substrate is wide, and a precision means for controlling this space is not necessary when compared to conventional apparatuses wherein an air layer is disposed between substrate 32 and probe 33, as in JP Kokai Unexamined Patent Publication 6[1994]-7494 and JP Kokai Unexamined Patent Publication 2002-22789. Moreover, a probe with a wide surface area for detection can be used for the inspection of substrates for panels with a small degree of flatness and a wide surface area to be detected; therefore, inspection throughput can be dramatically improved.

Furthermore, when a substrate for an organic EL panel is inspected with a layer of air serving as the space between substrate 32 and probe 33 as in the past, it is necessary to apply a potential difference of 2 V in the space in order to generate the 10 μA current necessary for emission by the organic EL element, making dielectric breakdown possible. However, a current of 10 μA can be generated at a potential difference of 0.2 V by supplying water 39 to the space and stable inspection can be performed as a result.

Next, a modified example of the embodiment of the present invention will be introduced. FIG. 4 is a close-up view of substrate 32 and probe 33 corresponding to FIG. 8 of the above-mentioned embodiment. This example differs from the above-mentioned embodiment in that electrode 41 on the probe is flat. Flat electrode 41 has an advantage in that production cost is inexpensive and alignment is simple when compared to array-shaped electrodes. An infinite number of fine holes (not shown) are made in electrode 41 and water 39 that has been supplied from water supply device 35 is in turn introduced from these holes in between substrate 32 and probe 33. The detection surface area that can be detected by the probe is the surface area of electrode 41 and the number of pixels that can be inspected without moving probe 33 increases as this detection surface area becomes wider. Therefore, a probe 33 having a larger detection surface area than the surface area of the pixel can be used in the present modification.

Moreover, a probe 33 that is approximately the same size as a pixel or is smaller than the surface area of the pixel can be used for substrates with a small degree of flatness or inspections that must be more accurate.

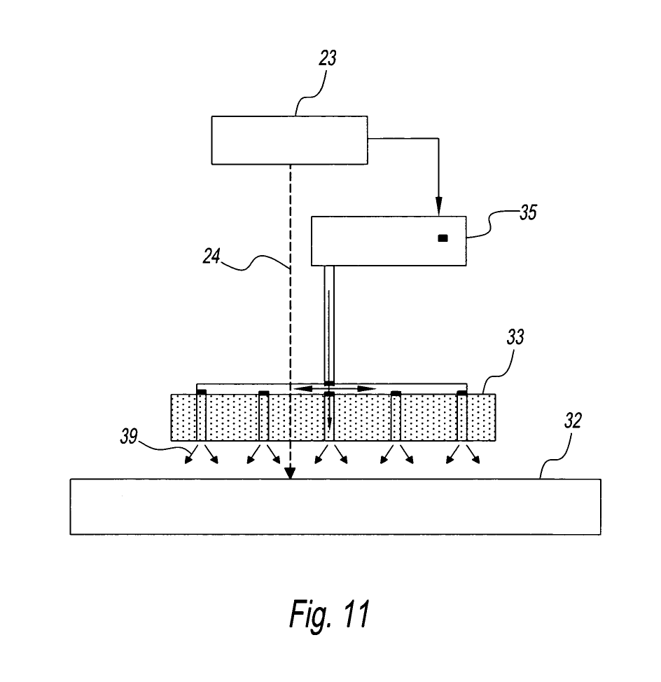

The space between substrate 32 and probe 33 can be controlled by the amount of water 39 that is supplied. FIG. 11 is a schematic illustration of this type of control device. Reference 23 is a measurement device that measures the space between substrate 32 and probe 33 using a laser 24 and 35 is a water supply device. Space measurement device 23 measures the space between substrate 32 and probe 33 using laser 24 during substrate inspection and outputs the difference from a pre-determined target value to water supply device 35. Water supply device 35 adjusts the amount of water that is supplied to probe 33 based on this difference. The water that has been supplied from water supply device 35 to probe 33 is introduced from fine holes in probe 33 in between substrate 32 and probe 33. Thus, a very small space of from several μm to several tens of μm can be maintained with stability by a simple structure by regular monitoring of the space between substrate 32 and probe 33 using space measurement device 23 and feeding this information back to water supply device 35.

The above-mentioned embodiment and modifications thereof are only one embodiment for describing the present invention according to the claims and it is clear to persons skilled in the art that various modifications can be applied within the priority of the claims.

What is claimed is:

1. An inspecting apparatus which comprises: a signal supply device for supplying signals to a thin-film transistor active matrix substrate for an organic EL panel; a probe positioned facing the substrate; a detector for detecting signals flowing to the probe; and a fluid supply device for supplying a dielectric fluid between the substrate and the probe.

2. The inspecting apparatus according to claim 1, wherein said signal supply device supplies non-standing wave signals.

3. The inspecting apparatus according to claim 1, wherein said dielectric fluid is a liquid comprised of polar molecules.

4. The inspecting apparatus according to claim 3, wherein said dielectric fluid is water.

5. The inspecting apparatus according to claim 1, wherein said probe has a plurality of electrodes for inspecting.

6. The inspecting apparatus according to claim 1, wherein said detector detects a current flowing to the probe.

7. A method for inspecting thin-film transistor active matrix substrates which comprises: bringing a probe opposite a thin-film transistor active matrix substrate for an organic EL panel; introducing a dielectric fluid between the substrate and the probe; supplying signals to a closed circuit consisting of the substrate, the dielectric fluid, and the probe; and detecting signals flowing to the closed circuit.

8. The method according to claim 7, wherein a detecting surface area of the probe is wider than the surface area of a pixel on the substrate.

9. A method for inspecting thin film transistor active matrix substrates which comprises: bringing a probe opposite a thin-film transistor active matrix substrate; introducing a dielectric fluid between the substrate and the probe; forming an air or nitrogen flow at the end face of the probe; discharging the dielectric fluid from between the end face of the probe and the air flow; supplying signals to a closed circuit consisting of the substrate, dielectric fluid, and probe; and detecting the signals flowing to the closed circuit.

10. A method for inspecting thin-film transistor active matrix substrates which comprises: bringing a probe opposite a thin-film transistor active matrix substrate; introducing a dielectric fluid between the substrate and the probe; supplying signals to a closed circuit consisting of the substrate, the dielectric fluid, and the probe; and detecting signals flowing to the closed circuit, wherein the distance between the substrate and the probe is controlled by the amount of dielectric fluid that is introduced.
